(19) United States
(12) Patent Application Publication
(10) Pub. No.: US 2025/0372926 A1
(43) Pub. Date: Dec. 4, 2025

(54) CONNECTOR WITH BUILT-IN FERRITE CORE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Yuki HASHIMOTO, Mie (JP); Seido NISHIJIMA, Mie (JP); Akio KIMURA, Mie (JP)

(21) Appl. No.: 18/875,162

(22) PCT Filed: Jun. 5, 2023
(86) PCT No.: PCT/JP2023/020736

§ 371 Date: Dec. 16, 2024

(30) Foreign Application Priority Data
Jun. 17, 2022 (JP) 2022-098273

(51) Int. Cl. H01R 13/7193

(52) U.S. Cl. CPC H01R 13/7193; H01R 2201/26

(57) ABSTRACT

A connector with a built-in ferrite core is disclosed which suppresses the damage of the ferrite core and has an excellent degree of freedom in selecting a resin material to be used. A connector 10 with a built-in ferrite core includes a terminal fitting 12, a ferrite core 14 to be arranged to surround the terminal fitting 12 and a connector housing 16 for accommodating the terminal fitting 12 and the ferrite core. The connector housing 16 includes a first resin portion 18 for holding the terminal fitting 12 in an embedded state and a second resin portion 20 for holding the first resin portion 18 and the ferrite core 14 in an embedded state.

### TECHNICAL FIELD

The present disclosure relates to a connector with a built-in ferrite core.

### BACKGROUND

Conventionally, a connector with a built-in ferrite core, in which a ferrite core is arranged around terminal fittings, has been used as disclosed in Patent Document 1 for the purpose of suppressing noise in power transmission between in-vehicle components. If the connector is formed with the ferrite core embedded together with the terminal fittings in a connector housing made of synthetic resin by insert molding, the ferrite core may be damaged due to a contraction force when a resin is cured. Accordingly, in Patent Document 1, it is proposed to mold the connector housing with an assembly of the terminal fittings and a core molded body surrounded in advance by a protecting portion made of a resin material softer than the connector housing as an insert. According to this, since the ferrite core is surrounded by the protecting portion made of the resin material softer than the connector housing, a contraction force of the connector housing during the molding of the connector housing is absorbed by the protecting portion and the damage of the ferrite core can be suppressed.

### PRIOR ART DOCUMENT

### Patent Document

Patent Document 1: JP 2015-053202 A

### SUMMARY OF THE INVENTION

### Problems to be Solved

However, in the structure of Patent Document 1, the protecting portion needs to be made of the resin material softer than the connector housing. Thus, for example, if the connector is required to have a high heat resistance, the heat resistance requirement may not be satisfied by the resin material of the protecting portion. Therefore, further improvement has been required.

Accordingly, a connector with a built-in ferrite core is disclosed which suppresses the damage of the ferrite core and has an excellent degree of freedom in selecting a resin material to be used.

### Means to Solve the Problem

The present disclosure is directed to a connector with a built-in ferrite core, the connector being provided with a terminal fitting, a ferrite core arranged to surround the terminal fitting and a connector housing for accommodating the terminal fitting and the ferrite core, the connector housing including a first resin portion for holding the terminal fitting in an embedded state and a second resin portion for holding the first resin portion and the ferrite core in an embedded state.

### Effect of the Invention

According to the present disclosure, it is possible to provide a connector with a built-in ferrite core which suppresses the damage of the ferrite core and has an excellent degree of freedom in selecting a resin material to be used.

### BRIEF DESCRIPTION OF THE DRAWINGS

FIG. 1 is a perspective view showing a connector with a built-in ferrite core according to a first embodiment with first and second resin portions shown in a see-through state.

FIG. 2 is a plan view of the connector with the built-in ferrite core shown in FIG. 1.

FIG. 3 is a section along III-III in FIG. 2.

FIG. 4 is a section along IV-IV in FIG. 2.

FIG. 5 is a perspective view showing terminal fittings constituting the connector with the built-in ferrite core shown in FIG. 1.

FIG. 6 is a perspective view showing the first resin portion constituting the connector with the built-in ferrite core shown in FIG. 1 with the terminal fittings embedded.

FIG. 7 is a perspective view showing a connector with a built-in ferrite core according to a second embodiment.

FIG. 8 is a perspective view showing a connector with a built-in ferrite core according to a third embodiment.

### DETAILED DESCRIPTION TO EXECUTE THE INVENTION

### <Description of Embodiments of Present Disclosure>

First, embodiments of the present disclosure are listed and described.

The connector with the built-in ferrite core of the present disclosure is provided with a terminal fitting, a ferrite core arranged to surround the terminal fitting and a connector housing for accommodating the terminal fitting and the ferrite core, the connector housing including a first resin portion for holding the terminal fitting in an embedded state and a second resin portion for holding the first resin portion and the ferrite core in an embedded state.

According to the connector with the built-in ferrite core of the present disclosure, the connector housing is divided into the first resin portion for holding the terminal fitting in the embedded state and the second resin portion for holding the first resin portion and the ferrite core in the embedded state. Thus, the connector with the built-in ferrite core can be formed as a secondary molded product by injection-molding the second resin portion with a primary molded product and the ferrite core as inserts after the first resin portion holding the terminal fitting in the embedded state is formed as the primary molded product. In this way, the amount of a resin in the secondary molded product including the ferrite core as an insert can be reduced by as much as the first resin portion, wherefore the damage of the ferrite core can be prevented or suppressed by reducing a contraction force applied to the ferrite core when a resin material of the second resin portion is cured.

Moreover, unlike Patent Document 1, the ferrite core needs not be covered by a resin material softer than the connector housing, and the first and second resin portions can be made of arbitrary materials. Therefore, a risk of damaging the ferrite core can be reduced even if a material relatively hard and high in heat resistance such as PBT (polybutylene terephthalate) is selected as the resin material, and it is possible to provide a connector with a built-in ferrite core having an excellent degree of freedom in selecting a resin material to be used.

Preferably, the second resin portion is made of a resin material higher in heat resistance than PVC. By dividing the connector housing into the first and second resin portions, the influence of a contraction force during the curing of the resin on the ferrite core is reduced. Thus, unlike a conventional structure, the ferrite core needs not be surrounded by a resin material (PVC (polyvinyl chloride) or the like) softer than the connector housing, and the second resin portion for surrounding the ferrite core can be made of a resin material higher in heat resistance than PVC. In this way, the heat resistance of the connector with the built-in ferrite core can be improved and the connector with the built-in ferrite core excellent in heat resistance performance can be provided. Preferable examples of the resin material higher in heat resistance than PVC include thermoplastic resins such as PBT, PPS (polyphenylene sulfide), PTFE (polytetrafluoroethylene) and PAI (polyamide-imide) and thermosetting resins such as PI (polyimide resin).

Preferably, the ferrite core is annularly arranged to surround the first resin portion, and the second resin portion integrally includes a filling portion for filling between an inner peripheral surface of the ferrite core and a facing surface of the first resin portion and an outer surface covering portion for covering an outer peripheral surface and a pair of axial end surfaces of the ferrite core. Since the second resin portion integrally includes the filling portion and the outer surface covering portion, the ferrite core can be stably held in the embedded state around the first resin portion. Moreover, since the second resin portion includes the filling portion and the outer surface covering portion as arrangement regions, the amount of the resin in each region can be advantageously adjusted.

Preferably, a projection projecting toward the inner peripheral surface of the ferrite core is provided on a surface of the first resin portion. Since the projection projecting toward the inner peripheral surface of the ferrite core is provided on the surface of the first resin portion, the amount of the resin of the filling portion of the second resin portion tending to have a large resin thickness can be reduced by a volume of the projection, and the damage of the ferrite core can be further suppressed by reducing a contraction force in the filling portion during the curing of the second resin portion.

Preferably, a plurality of the projections are distributed and arranged on the surface of the first resin portion while being spaced apart from each other in a circumferential direction. Since the plurality of projections are distributed and arranged on the surface of the first resin portion while being spaced apart from each other in the circumferential direction, the amount of the resin of the filling portion of the second resin portion can be reduced by the plurality of projections. Further, each projection can be small and it is possible to prevent troubles such that the first resin portion is deformed to cause a position shift of the terminal fitting due to sinks of the projections during the curing of the first resin portion.

Preferably, the outer surface covering portion includes an exposure hole for exposing the ferrite core. This is because the amount of the resin of the outer surface covering portion is reduced by the exposure hole and the damage of the ferrite core due to a contraction force during the curing of the second resin portion can be more advantageously prevented or suppressed.

### <Details of Embodiments of Present Disclosure>

Specific examples of a connector with a built-in ferrite core of the present disclosure are described below with reference to the drawings. Note that the present disclosure is not limited to these illustrations, but is represented by claims and intended to include all changes in the scope of claims and in the meaning and scope of equivalents.

### First Embodiment

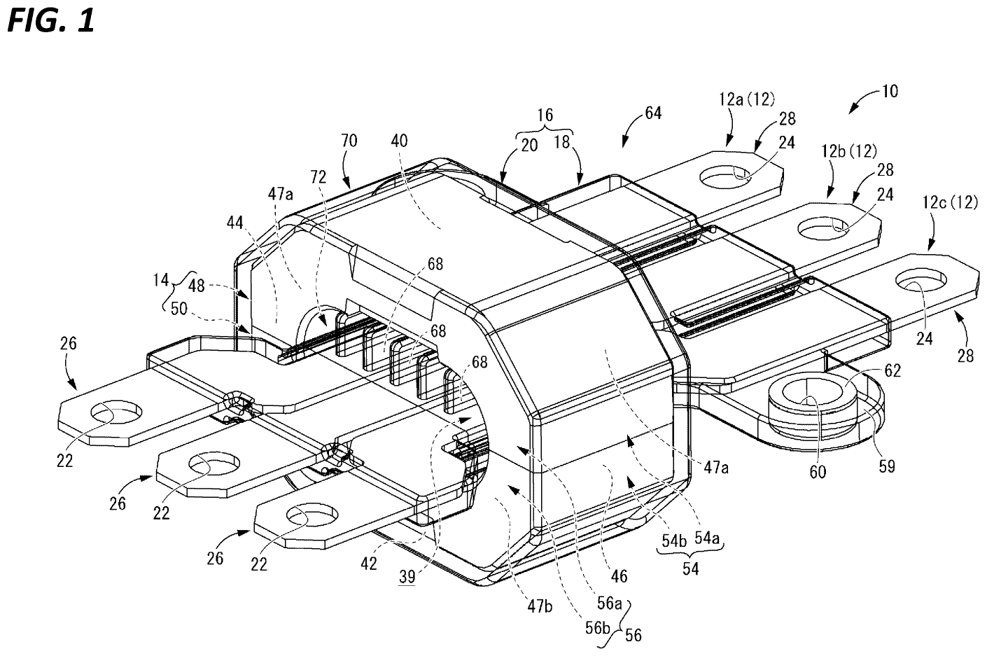

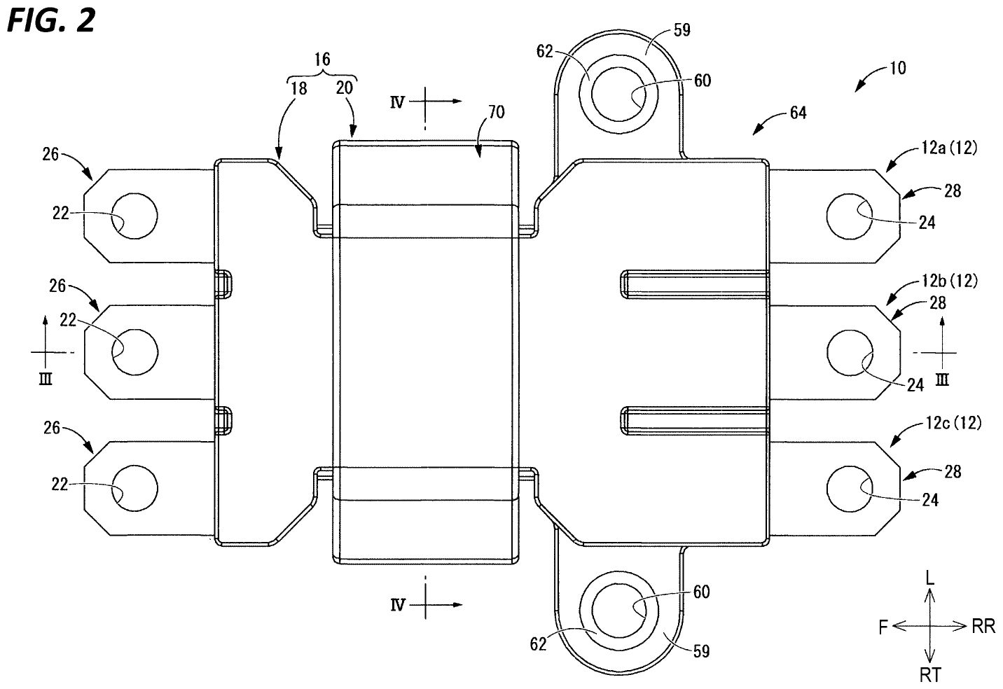

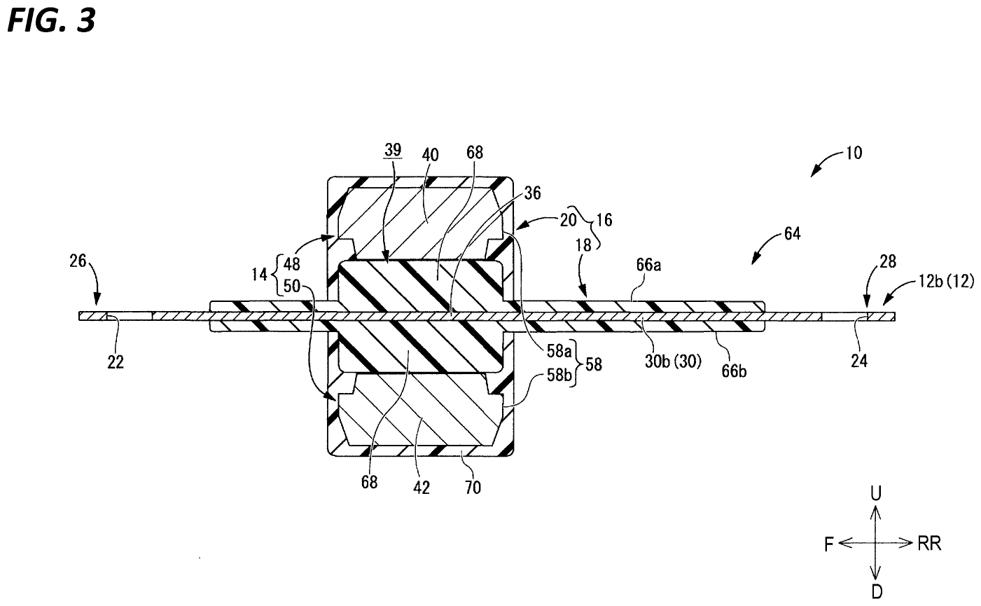

Hereinafter, a connector 10 with a built-in ferrite core of a first embodiment of the present disclosure is described using FIGS. 1 to 6. The connector 10 with the built-in ferrite core is, for example, a connector for connecting a motor and a PCU (Power Control Unit), one side of each terminal fitting 12 in the connector 10 with the built-in ferrite core is electrically connected to the unillustrated motor, and the other side of each terminal fitting 12 is electrically connected to the unillustrated PCU. Note that the connector 10 with the built-in ferrite core can be arranged in an arbitrary orientation, but upper and lower sides in FIG. 3 are referred to as upper and lower sides, left and right sides in FIG. 2 are referred to as front and rear sides, and upper and lower sides in FIG. 2 are referred to as left and right sides below. Further, for a plurality of identical members, only some members may be denoted by a reference sign and the other members may not be denoted by the reference sign.

(Connector 10 with Built-in Ferrite Core)

The connector 10 with the built-in ferrite core is provided with the terminal fittings 12, a ferrite core 14 arranged to surround the terminal fittings 12 and a connector housing 16 for accommodating the terminal fittings 12 and the ferrite core 14. Further, the connector housing 16 includes a first resin portion 18 for holding the terminal fittings 12 in an embedded state and a second resin portion 20 for holding the first resin portion 18 and the ferrite core 14 in an embedded state. Note that members inside the first and second resin portions 18, 20 are respectively shown in a see-through state in FIG. 1.

### (Terminal Fittings 12)

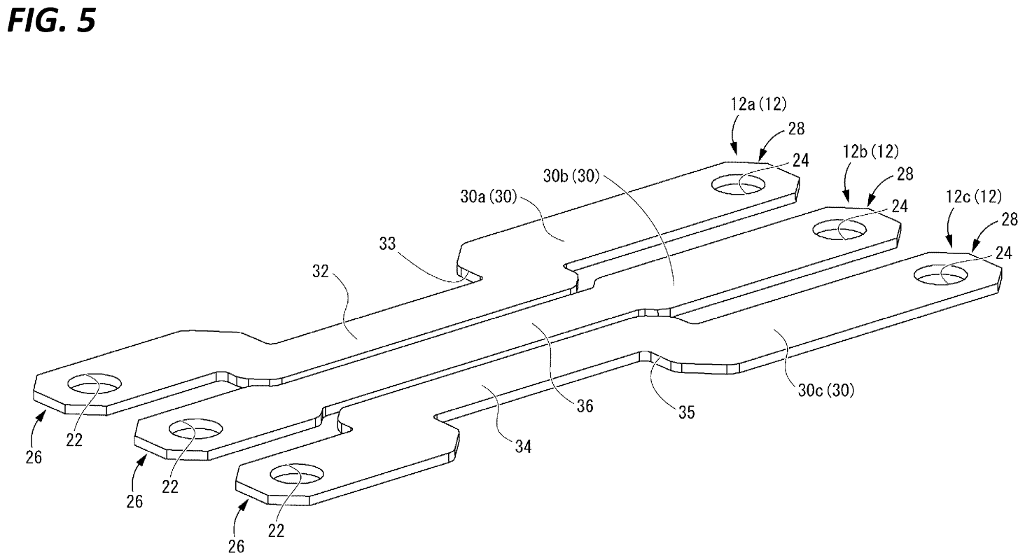

As also shown in FIG. 5, in the first embodiment, a plurality of the terminal fittings 12 are provided; a first terminal fitting 12a, a second terminal fitting 12b and a third terminal fitting 12c in this order from left. Each of the terminal fittings 12 (first to third terminal fittings 12a to 12c) is constituted by a busbar and, for example, made of electrically conductive metal such as copper, copper alloy, aluminum or aluminum alloy. In the first embodiment, each of the first to third terminal fittings 12a to 12c has a flat plate shape extending in parallel to a horizontal plane (plane orthogonal to a vertical direction) without having recesses and projections. Particularly in the first embodiment, the first to third terminal fittings 12a to 12c have substantially constant dimension in a length direction (dimension in a front-rear direction) and dimension in a width direction (dimension in a lateral direction) as a whole and respectively extend in the front-rear direction.

In a front end part of each of the first to third terminal fittings 12a to 12c is formed with a substantially circular front through hole 22 penetrating in a plate thickness direction (vertical direction). Further, in a rear end part of each of the first to third terminal fittings 12a to 12c is formed with a substantially circular rear through hole 24 penetrating in the plate thickness direction (vertical direction). In this way, one terminal portion 26 is formed in the front end part, which is one end part, in each of the first to third terminal fittings 12a to 12c, and each one terminal portion 26 is electrically connected to the unillustrated motor. Further, another terminal portion 28 is formed in the rear end part, which is another end part, in each of the first to third terminal fittings 12a to 12c, and each other terminal portion 28 is electrically connected to the unillustrated PCU. An intermediate part in the front-rear direction between the one terminal portion 26 and the other terminal portion 28 in each of the first to third terminal fittings 12a to 12c serves as an intermediate portion 30 (each of first to third intermediate portions 30a to 30c).

In the first embodiment, a dimension in the lateral direction from the left end of the first terminal fitting 12a to the right end of the third terminal fitting 12c in the intermediate parts in the front-rear direction (first to third intermediate portions 30a to 30b) in the first to third terminal fittings 12a to 12c arranged side by side in the lateral direction is smaller than in other parts (e.g. front and rear end parts of the first to third terminal fittings 12a to 12c).

That is, the intermediate part in the front-rear direction of the first terminal fitting 12a is provided with a rightward projecting portion 32 projecting rightward with respect to the front and rear end parts and bent substantially in a crank manner with respect to the front and rear end parts. In this way, a left recess 33 open leftward is formed at the formation position of the rightward projecting portion 32 in a left end part of the first terminal fitting 12a. Similarly, the intermediate part in the front-rear direction of the third terminal fitting 12c is provided with a leftward projecting portion 34 projecting leftward with respect to the front and rear end parts and bent substantially in a crank manner with respect to the front and rear end parts. In this way, a right recess 35 open rightward is formed at the formation position of the leftward projecting portion 34 in a right end part of the third terminal fitting 12c. Further, the intermediate part in the front-rear direction of the second terminal fitting 12b is provided with recesses open outward in the lateral direction in both lateral end parts, thereby forming a narrow portion 36 having a smaller dimension in the width direction (dimension in the lateral direction) than the front and rear end parts.

These rightward projecting portion 32, narrow portion 36 and leftward projecting portion 34 are respectively provided substantially at the same positions in the front-rear direction of the first to third terminal fittings 12a to 12c and respectively have a substantially equal dimension in the front-rear direction. That is, the rightward projecting portion 32 in the first terminal fitting 12a is proximate to the left recess constituting the narrow portion 36 in the second terminal fitting 12b (or the rightward projecting portion 32 enters the left recess in the narrow portion 36). Further, the leftward projecting portion 34 in the third terminal fitting 12c is proximate to the right recess constituting the narrow portion 36 in the second terminal fitting 12b (or the leftward projecting portion 34 enters the right recess in the narrow portion 36).

In this way, in the first to third terminal fittings 12a to 12c, the dimension in the lateral direction from the left end of the first terminal fitting 12a to the right end of the third terminal fitting 12c is smaller at the formation positions of the rightward projecting portion 32, the narrow portion 36 and the leftward projecting portion 34 than those in the front and rear end parts. In a part where the dimension in the lateral direction from the left end of the first terminal fitting 12a to the right end of the third terminal fitting 12c is made smaller, an arrangement region 38 in which the ferrite core 14 is arranged is configured to include the internal spaces of the left and right recesses 33, 35.

### (Ferrite Core 14)

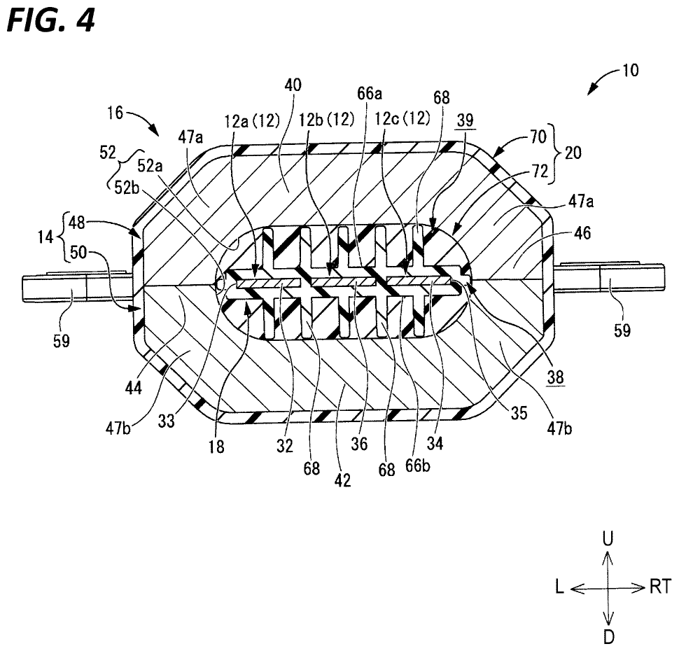

As also shown in FIG. 4 and the like, the ferrite core 14 has an annular shape as a whole and an internal space 39 thereof has a laterally long elliptical cross-section having a maximum lateral dimension larger than a maximum vertical dimension. Further, the ferrite core 14 has a predetermined dimension in the front-rear direction, which is smaller than dimensions in the front-rear direction of the left and right recesses 33, 35 constituting the arrangement region 38. In this way, when the ferrite core 14 (upper and lower ferrite cores 48, 50) is arranged around the first resin portion 18 holding the first to third terminal fittings 12a to 12c as described later, circumferential end parts of the upper and lower ferrite cores 48, 50 are easily inserted into the left and right recesses 33, 35. A conventionally known material is used for the ferrite core 14. In the first embodiment, the ferrite core 14 is made of Mn—Zn based ferrite.

This ferrite core 14 is disposed to cover the rightward projecting portion 32, the narrow portion 36 and the leftward projecting portion 34 in the part where the dimension in the lateral direction from the left end of the first terminal fitting 12a to the right end of the third terminal fitting 12c is made smaller in the first to third terminal fittings 12a to 12c. That is, the ferrite core 14 includes an upper part 40 and a lower part 42 for respectively covering the rightward projecting portion 32, the narrow portion 36 and the leftward projecting portion 34 from above and below. Further, the ferrite core 14 includes a left part 44 to be inserted into the left recess 33 in the arrangement region 38 of the ferrite core 14 and a right part 46 to be inserted into the right recess 35 in the arrangement region 38.

These upper, left and right parts 40, 44 and 46 are respectively connected by upper connecting portions 47a, and the lower, left and right parts 46 are respectively connected by lower connecting portions 47b. Each of these upper and lower connecting portions 47a, 47b extends in an oblique direction inclined with respect to the vertical direction and a horizontal direction (direction orthogonal to the vertical direction).

In the first embodiment, the ferrite core 14 is divisible in the vertical direction and composed of the upper ferrite core 48 located on an upper side and a lower ferrite core 50 located on a lower side. That is, both of the upper and lower ferrite cores 48, 50 have a half cylindrical shape and both circumferential end surfaces of the upper and lower ferrite cores 48, 50 are overlapped each other in the vertical direction, thereby covering the openings thereof each other to form the elliptical internal space 39.

In short, the upper and lower parts 40, 42 of the ferrite core 14 respectively having a predetermined lateral dimension are constituted by circumferential intermediate parts of the upper and lower ferrite cores 48, 50. Further, the respective upper connecting portions 47a are constituted by both circumferential side parts of the upper ferrite core 48, and the respective lower connecting portions 47b are constituted by both circumferential side parts of the lower ferrite core 50. The left part 44 of the ferrite core 14 is constituted by overlapping left circumferential end parts of the respective upper and lower ferrite cores 48, 50. Similarly, the right part 46 of the ferrite core 14 is constituted by overlapping right circumferential end parts of the respective upper and lower ferrite cores 48, 50.

Further, an inner peripheral surface 52 of the ferrite core 14 is composed of an inner peripheral surface 52a of the upper ferrite core 48 and an inner peripheral surface 52b of the lower ferrite core 50, and an outer peripheral surface 54 of the ferrite core 14 is composed of an outer peripheral surface 54a of the upper ferrite core 48 and an outer peripheral surface 54b of the lower ferrite core 50. Further, a front end surface 56, which is one axial end surface of the ferrite core 14, is composed of a front end surface 56a of the upper ferrite core 48 and a front end surface 56b of the lower ferrite core 50, and a rear end surface 58, which is the other axial end surface of the ferrite core 14, is composed of a rear end surface 58a of the upper ferrite core 48 and a rear end surface 58b of the lower ferrite core 50.

### (Connector Housing 16)

The connector housing 16 includes the first and second resin portions 18, 20 as described above. Synthetic resin materials constituting these first and second resin portions 18, 20 are not limited, but each resin portion is preferably made of a highly heat-resistant resin material. Further, the synthetic resin materials constituting the first and second resin portions 18, 20 may be the same or may be different. In the first embodiment, the first and second resin portions 18, 20 are both made of PBT (polybutylene terephthalate), which is a resin material higher in heat resistance than PVC (polyvinyl chloride). Note that examples of the resin material higher in heat resistance than PVC include thermoplastic resins such as PBT, PPS (polyphenylene sulfide), PTFE (polytetrafluoroethylene) and PAI (polyamide-imide) and thermosetting resins such as PI (polyimide resin). These materials can be suitably used as the materials of the first and second resin portions 18, 20.

### (First Resin Portion 18)

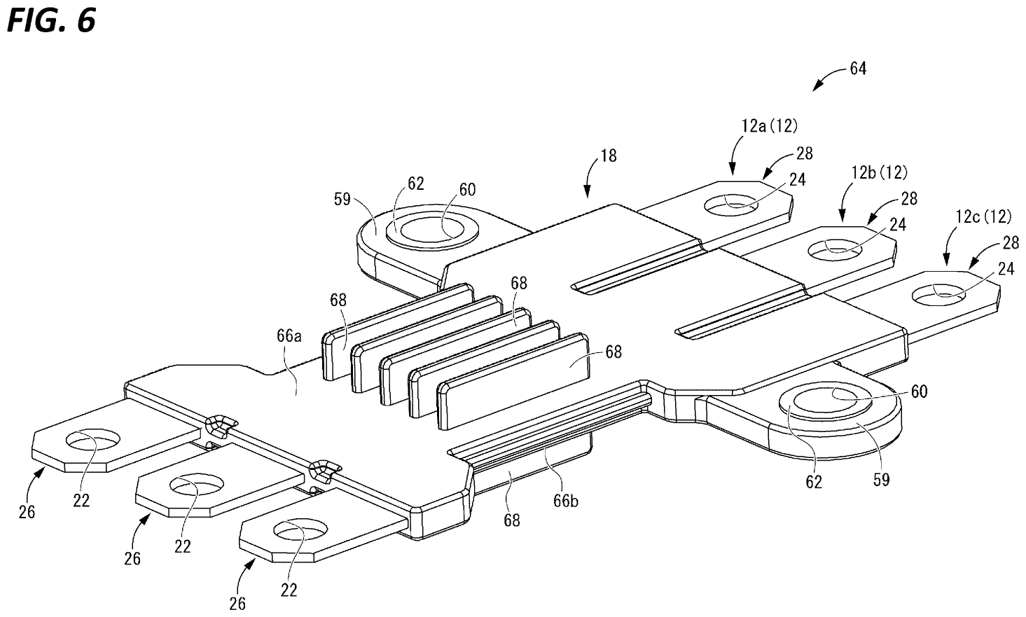

As shown in FIG. 6, the first resin portion 18 holds the respective terminal fittings 12 (first to third terminal fittings 12a to 12c) in an embedded state. Specifically, the first resin portion 18 substantially entirely covers the intermediate parts in the front-rear direction (first to third intermediate portions 30a to 30c) in the respective terminal fittings 12 (first to third terminal fittings 12a to 12c). In other words, in each of the first to third terminal fittings 12a to 12c), the one terminal portion 26 (front terminal portion) projects forward from the first resin portion 18, and the other terminal portion 28 (rear terminal portion) projects rearward from the first resin portion 18. In the first embodiment, as also shown in FIGS. 3 and 4, the first resin portion 18 having a substantially constant thickness is fixed to the substantially entire surfaces of predetermined regions (first to third intermediate portions 30a to 30b) in the respective terminal fittings 12 (first to third terminal fittings 12a to 12b).

Further, leg portions 59 projecting laterally outward are provided on both lateral end parts of a rear part of the first resin portion 18. These leg portions 59 are provided laterally outward of the first and third terminal fittings 12a, 12c, and a collar 62 made of metal and having a bolt insertion hole 60 is provided in each leg portion 59. That is, a pair of the collars 62, 62 are held by the respective leg portions 59 in the first resin portion 18 on sides laterally outward of the first and third terminal fittings 12a, 12c in the rear part of the first resin portion 18. The connector 10 with the built-in ferrite core is fixed to the motor or the PCU to be connected to the one terminal portion 26 or the other terminal portion 28 of each terminal fitting 12 or an in-vehicle component arranged between these by unillustrated bolts inserted through these bolt insertion holes 60.

In the first embodiment, the first resin portion 18 is formed as an integrally molded product (primary molded product 64) provided with the first to third terminal fittings 12a to 12c and the pair of collars 62, 62. In short, the primary molded product 64 shown in FIG. 6 is formed by injection-molding the resin material (PBT) for constituting the first resin portion 18 with the first to third terminal fittings 12a to 12c and the pair of collars 62, 62 set in a cavity for molding the first resin portion 18 during the molding of the first resin portion 18.

Here, projections 68 projecting toward both sides in the vertical direction from an upper surface 66a and a lower surface 66b, which are surfaces of the first resin portion 18, are provided in a part of the first resin portion 18 covering the rightward projecting portion 32, the narrow portion 36 and the leftward projecting portion 34 in the first to third terminal fittings 12a to 12c. In the first embodiment, a plurality of (five) projections 68 are distributed and arranged on each of the upper and lower surfaces 66a, 66b of the first resin portion 18 while being spaced apart from each other in the width direction (lateral direction), which is a circumferential direction. The respective projections 68 have the same shape and, in the first embodiment, substantially in the form of rectangular flat plates.

As described above, since the ferrite core 14 (upper and lower ferrite cores 48, 50) are arranged on an outer peripheral side of the part of the first resin portion 18 covering the rightward projecting portion 32, the narrow portion 36 and the leftward projecting portion 34 in the first to third terminal fittings 12a to 12c, the respective projections 68 project toward the inner peripheral surface 52 of the ferrite core 14. In short, the respective projections 68 projecting upward project toward the inner peripheral surface 52a of the upper ferrite core 48, and the respective projections 68 projecting downward project toward the inner peripheral surface 52b of the lower ferrite core 50. In other words, the rightward projecting portion 32, the narrow portion 36 and the leftward projecting portion 34 in the first to third terminal fittings 12a to 12c, the first resin portion 18 covering these and the respective projections 68 projecting outward in the vertical direction from the first resin portion 18 are arranged in the internal space 39 of the ferrite core 14. In this way, the ferrite core 14 is annularly arranged to surround the first resin portion 18.

Note that the projecting tips of the respective projections 68 projecting outward in the vertical direction from the surfaces (upper surface 66a and lower surface 66b) of the first resin portion 18 may be in contact with the inner peripheral surface 52 (inner peripheral surfaces 52a, 52b) of the ferrite core 14 or may be separated therefrom by a predetermined distance. In the first embodiment, the projecting tips of the respective projections 68 are facing the inner peripheral surface 52 (inner peripheral surfaces 52a, 52b) of the ferrite core 14 in the vertical direction while being slightly separated therefrom.

### (Second Resin Portion 20)

The second resin portion 20 is provided on an outer peripheral side of the ferrite core 14 with the ferrite core 14 arranged on the outer peripheral side of the first resin portion 18 holding first to third terminal fittings 12a to 12c, and holds the first resin portion 18 and the ferrite core 14 in an embedded state. That is, the second resin portion 20 includes an outer surface covering portion 70 for covering the outer peripheral surface 54 and the front end surface 56 and the rear end surface 58, which are a pair of the axial end surfaces, of the ferrite core 14. In the first embodiment, as also shown in FIGS. 3 and 4, the outer surface covering portion 70 having a substantially constant thickness is fixed to the substantially entire outer peripheral surface 54, front end surface 56 and rear end surface 58 of the ferrite core 14.

Further, the second resin portion 20 is also filled in the internal space 39 of the ferrite core 14. Specifically, the second resin portion 20 includes a filling portion 72 filled between the inner peripheral surface 52 of the ferrite core 14 and the facing surface of the first resin portion 18, i.e. between the inner peripheral surface 52a of the upper ferrite core 48 and the upper surface 66a of the first resin portion 18, which are vertically facing surfaces, and between the inner peripheral surface 52b of the lower ferrite core 50 and the lower surface 66b of the first resin portion 18, which are vertically facing surfaces. That is, the filling portion 72 is fixed to face the respective inner peripheral surfaces 52a, 52b of the upper and lower ferrite cores 48, 50 and the upper and lower surfaces 66a, 66b of the first resin portion 18. Such a second resin portion 20 integrally includes the outer surface covering portion 70 provided outside the ferrite core 14 and the filling portion 72 provided inside the ferrite core 14.

In the first embodiment, the second resin portion 20 is formed as an integrally molded product (secondary molded product) provided with the primary molded product 64 and the ferrite core 14, and the connector 10 with the built-in ferrite core is configured by this secondary molded product. In short, the second resin portion 20 is formed by injection-molding the resin material (PBT) for constituting the second resin portion 20 with the ferrite core 14 (upper and lower ferrite cores 48, 50) set on an outer peripheral side of the primary molded product 64 in a cavity for molding the second resin portion 20 during the molding of the second resin portion 20. In this way, the connector 10 with the built-in ferrite core shown in FIGS. 1 to 4 is formed at the same time as the second resin portion 20 and the connector housing 16 are formed.

(Manufacturing Method of Connector 10 with Built-In Ferrite Core)

A specific example of a manufacturing method of the connector 10 with the built-in ferrite core is described below. Note that the manufacturing method of the connector 10 with the built-in ferrite core is not limited to the one described below.

First, the first to third terminal fittings 12a to 12c and the pair of collars 62, 62 are prepared. Then, in the cavity for molding the first resin portion 18, the first to third terminal fittings 12a to 12c are arranged side by side in the lateral direction as shown in FIG. 5 and the pair of collars 62, 62 are arranged laterally outward of the first and third terminal fittings 12a, 12c. Thereafter, the first resin portion 18 is molded by injecting the resin material (PBT) for constituting the first resin portion 18 into the cavity for molding the first resin portion 18. After molding, a mold is opened to obtain the primary molded product 64.

Subsequently, the upper and lower ferrite cores 48, 50 are arranged from above and below the respective projections 68 of the primary molded product 64 in the vertical direction, the both circumferential end surfaces of the upper and lower ferrite cores 48, 50 are butted and overlapped each other, and the primary molded product 64 and the upper and lower ferrite cores 48, 50 in this state are set in the cavity for molding the second resin portion 20. Then, the second resin portion 20 is molded by injecting the resin material (PBT) for constituting the second resin portion 20 into the cavity for molding the second resin portion 20. In this way, the connector housing 16 is formed at the same time as the second resin portion 20 is formed. After molding, a mold is opened to obtain the connector 10 with the built-in ferrite core as the secondary molded product, and the manufacturing of the connector 10 with the built-in ferrite core is completed.

In the connector 10 with the built-in ferrite core manufactured in this way, each one terminal portion 26 (front terminal portion) is electrically connected to the unillustrated motor and each other terminal portion 28 (rear terminal portion) is electrically connected to the unillustrated PCU. Further, the connector 10 with the built-in ferrite core is fixed to the motor, the PCU or a suitable in-vehicle component other than those by the unillustrated bolts inserted through the bolt insertion holes 60 of the respective collars 62 provided in the respective leg portions 59. Since the ferrite core 14 is arranged around the respective terminal fittings 12 (first to third terminal fittings 12a to 12c) in such a connector 10 with the built-in ferrite core, noise in power transmission between the motor and the PCU is suppressed by this ferrite core 14.

According to the connector 10 with the built-in ferrite core of the first embodiment, the connector housing 16 includes the first resin portion 18 for holding the respective terminal fittings 12 in the embedded state and the second resin portion 20 for holding the first resin portion 18 and the ferrite core 14 in the embedded state. The first resin portion 18 is formed as the integrally molded product (primary molded product 64) provided with the respective terminal fittings 12 (first to third terminal fittings 12a to 12c). Further, the second resin portion 20 is formed as the integrally molded product (secondary molded product) provided with the primary molded product 64 and the ferrite core 14. That is, the filling portion 72 of the second resin portion 20 is filled also inside the ferrite core 14. Since the second resin portion 20 is molded with the primary molded product 64 arranged inside the ferrite core 14, the amount of the resin material of the second resin portion 20, particularly the resin material of the filling portion 72, can be reduced. In short, by configuring the connector housing 16 to include the first and second resin portions 18, 20, the amount of the resin material necessary for one molding can be reduced, for example, as compared to the case where a connector housing is molded with respective terminal fittings merely arranged inside a ferrite core. Therefore, the damage of the ferrite core 14 due to the contraction of the resin material or the like during the molding of the second resin portion 20 can be avoided.

In this way, a degree of freedom in selecting the material of a member for surrounding the ferrite core 14 is improved and the resin material (PBT in the first embodiment) higher in heat resistance than PVC can be used as the resin material of the second resin portion 20, which is a member for surrounding the ferrite core 14. As a result, it is possible to provide the connector 10 with the built-in ferrite core excellent in heat resistance.

The ferrite core 14 is annularly arranged to surround the first resin portion 18, and the second resin portion 20 integrally includes the filling portion 72 to be filled inside the ferrite core 14 and the outer surface covering portion 70 for covering the outside of the ferrite core 14. By arranging the first resin portion 18 (primary molded product 64) inside the ferrite core 14, a reduction in the resin material of the filling portion 72 can be more reliably realized. Further, by molding the second resin portion 20 with the primary molded product 64 and the ferrite core 14 set in the cavity, the filling portion 72 and the outer surface covering portion 70 can be integrally formed, wherefore the manufacturing efficiency of the second resin portion 20 and, consequently, the connector 10 with the built-in ferrite core is also improved. Particularly, since the ferrite core 14 is structured to be vertically divisible, an operation of arranging the ferrite core 14 to surround the first resin portion 18 can be easily performed.

The projections 68 projecting toward the inner peripheral surface 52 of the ferrite core 14 are provided on the surfaces (upper surface 66a and lower surface 66b) of the first resin portion 18. In this way, the amount of the resin material of the filling portion 72 can be more reduced during the molding of the second resin portion 20, and the damage of the ferrite core 14 when the second resin portion 20 contracts is more reliably avoided.

Particularly, the plurality of projections 68 are distributed and arranged on the surfaces (upper surface 66a and lower surface 66b) of the first resin portion 18 while being spaced apart from each other. In this way, the amount of the resin material of the filling portion 72 can be even more reduced during the molding of the second resin portion 20, and the damage of the ferrite core 14 when the second resin portion 20 contracts can be even more reliably avoided. Further, as compared to the case where a single large projection is provided on a surface of a first resin portion, it is possible to reduce a possibility of bending or damaging the respective terminal fittings 12 (first to third terminal fittings 12a to 12c) located inside the first resin portion 18 due to the contraction of the first resin portion 18 or the like during the molding of the first resin portion 18.

### Second Embodiment

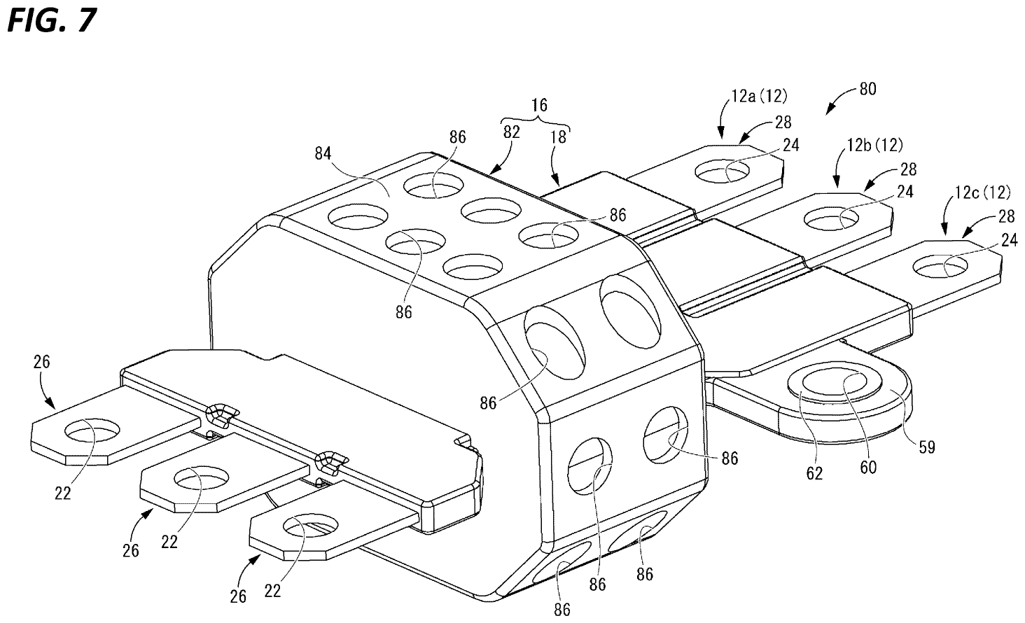

A connector 80 with a built-in ferrite core of a second embodiment of the present disclosure is described below using FIG. 7. The connector 80 with the built-in ferrite core of the second embodiment is structured similarly to the connector 10 with the built-in ferrite core of the first embodiment, but differs in that an outer surface covering portion 84 of a second resin portion 82 includes exposure holes 86 for exposing a ferrite core 14. Note that, in the following description, substantially the same members and parts as those of the first embodiment are denoted by the same reference signs as in the first embodiment and not described in detail.

Specifically, the exposure holes 86 penetrating through the outer surface covering portion 84 in the vertical direction or the lateral direction are formed in the outer surface covering portion 84, particularly in a part covering an outer peripheral surface 54 (outer peripheral surfaces 54a, 54b) of the ferrite core 14. In the second embodiment, a plurality of the exposure holes 86 having a substantially circular shape in a plan view or a side view are formed and arranged in alignment while being spaced apart by a predetermined distance in a circumferential direction of the outer surface covering portion 84 and the front-rear direction. The outer peripheral surface 54 (outer peripheral surfaces 54a, 54b) of the ferrite core 14 is exposed to outside through the plurality of these exposure holes 86.

Note that, in parts of the second resin portion 82 for covering a left part 44 and a right part 46 of the ferrite core 14 from laterally outer sides, a plurality of the exposure holes 86 having a substantially circular shape in the side view are formed to penetrate through the second resin portion 82 in the lateral direction. Further, in other parts of the second resin portion 82 (parts for covering an upper part 40 and a lower part 42 of the ferrite core 14 and upper connecting portions 47a and lower connecting portions 47b respectively extending in an oblique direction from outside), a plurality of the exposure holes 86 having a substantially circular shape in the plan view are formed to penetrate through the second resin portion 82 in the vertical direction.

Since a connector housing 16 includes a first resin portion 18 and the second resin portion 82 also in the connector 80 with the built-in ferrite core of the second embodiment, effects similar to those of the connector 10 with the built-in ferrite core of the first embodiment can be exhibited. That is, the amount of a resin material of the second resin portion 82 (filling portion 72) to be filled inside the ferrite core 14 can be reduced by providing the first resin portion 18 inside the ferrite core 14. In addition to that, the plurality of exposure holes 86 are provided in the outer surface covering portion 84 of the second resin portion 82 in the second embodiment, whereby the amount of the resin material of the second resin portion 82 (outer surface covering portion 84) provided outside the ferrite core 14 can also be reduced. As a result, the amount of the resin material of the second resin portion 82 can be even more reduced, and a possibility of damaging the ferrite core 14 due to the contraction of the resin material or the like can be even more reduced during the molding of the second resin portion 82.

Further, since the outer peripheral surface 54 (outer peripheral surfaces 54a, 54b) of the ferrite core 14 is exposed to outside through the plurality of exposure holes 86, heat can be dissipated to an outside space through the plurality of exposure holes 86 also when the ferrite core 14 generates heat in absorbing noise, and the connector 80 with the built-in ferrite core excellent in thermal performance can be provided.

### Third Embodiment

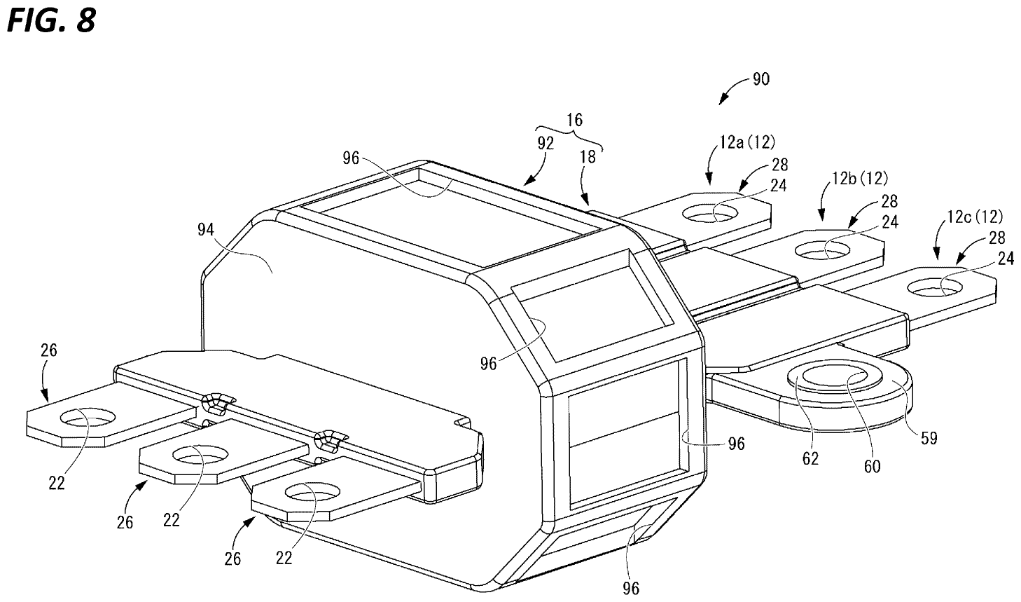

A connector 90 with a built-in ferrite core of a third embodiment of the present disclosure is described below using FIG. 8. The connector 90 with the built-in ferrite core of the third embodiment includes exposure holes 96 for exposing a ferrite core 14 in an outer surface covering portion 94 of a second resin portion 92 similarly to the connector 80 with the built-in ferrite core of the second embodiment. In this way, the connector 90 with the built-in ferrite core of the third embodiment can exhibit effects similar to those of the connector 80 with the built-in ferrite core of the second embodiment.

Note that although the substantially circular exposure holes 86 are provided in the second embodiment, the exposure holes 96 having a substantially rectangular shape in a plan view or a side view are provided in the third embodiment. Further, although a plurality of the exposure holes 96 are spaced apart by a predetermined distance in a circumferential direction in the outer surface covering portion 94 also in the third embodiment, a cross-sectional area of one exposure hole 96 is larger than that of one exposure hole 86 in the second embodiment. In the third embodiment, the sum of the cross-sectional areas of the plurality of exposure holes 96 is larger than that of the cross-sectional areas of the plurality of exposure holes 86 in the second embodiment. In this way, a resin material of a part constituting the outer surface covering portion 94 in the second resin portion 92 can be less than that of the outer surface covering portion 84 in the second embodiment, with the result that a possibility of damaging the ferrite core 14 due to the contraction of the resin material or the like can be even more reduced during the molding of the second resin portion 92.

### Other Embodiments

The technique described in this specification is not limited to the above described and illustrated embodiments, but the following embodiments are, for example, also included in the technical scope of the technique described in this specification.

(1) Although the rightward projecting portion 32 (left recess 33), the narrow portion 36 and the leftward projecting portion 34 (right recess 35) are provided in the respective terminal fittings 12 (first to third terminal fittings 12a to 12c) in the above embodiments, at least one of the terminal fittings may extend substantially straight in the front-rear direction. Note that, although three terminal fittings 12 (first to third terminal fittings 12a to 12c) are provided in the above embodiments, the number of the terminal fittings is not limited, one, two, four or more terminal fittings may be provided.

(2) Although five projections 68 substantially in the form of rectangular flat plates are provided on each of the upper and lower surfaces 66a, 66b of the first resin portion 18 in the above embodiments, the number, the shape and the like of projections are not limited. For example, one to four projections may be provided on each of the upper and lower surfaces of a first resin portion or six or more projections may be provided. Further, the shape of the projection in the side view is not limited to a substantially rectangular shape, but may be a triangular shape, a polygonal shape with five or more sides, a semicircular shape or the like or these shapes may be used in combination. Further, projection(s) may be provided only on either one of the upper and lower surfaces of the first resin portion or may be also provided, for example, on the left and right end surfaces of the first resin portion instead of or in addition to the upper and lower surfaces. Note that, in the connector with the built-in ferrite core according to the present disclosure, the projections provided on the first resin portion are not essential.

(3) Although the projecting tips of the respective projections 68 are facing the inner peripheral surface 52 (inner peripheral surfaces 52a, 52b) while being slightly separated therefrom in the above embodiments, there is no limitation to this mode. That is, the projecting tips of the respective projections may be in contact with the inner peripheral surface of the ferrite core. In this way, when the upper and lower ferrite cores are arranged from outer sides of the first resin portion in the vertical direction, the vertical positions of the upper and lower ferrite cores may be specified by the contact of the respective projections with the respective inner peripheral surfaces of the of the upper and lower ferrite cores. That is, the both circumferential end surfaces of the upper and lower ferrite cores may not be overlapped each other in the vertical direction and may be facing slightly away from each other in the vertical direction.

(4) Although the exposure holes 86, 96 penetrating through the second resin portion 82, 92 are provided in the outer surface covering portion 84, 94 of the second resin portion 82, 92 in the second and third embodiments, there is no limitation to this mode. That is, bottomed recesses open toward an outer peripheral side may be, for example, provided in an outer surface covering portion in a second resin portion. A reduction in the amount of the resin material in the second resin portion is achieved also by this. Further, in that case, the recesses may be provided in parts for covering axial end surfaces of the ferrite core in the outer surface covering portion of the second resin portion instead of or in addition to the part for covering the outer peripheral surface of the ferrite core in the outer surface covering portion of the second resin portion.

(5) Although the respective exposure holes 86, 96 are formed to penetrate through the second resin portion 82, 92 in the vertical direction or the lateral direction in the second and third embodiments, the respective exposure holes may be formed through the second resin portion in a thickness direction. That is, in the second and third embodiments, the exposure holes 86, 96 provided in the parts for covering the respective upper connecting portions 47a and the respective lower connecting portions 47b extending in the oblique direction are also formed to penetrate through the second resin portion 82, 92 in the vertical direction in the outer surface covering portion 84, 94 of the second resin portion 82, 92, but the exposure holes provided in these parts may be formed to penetrate through the second resin portion in the oblique direction.

List of Reference Numerals

| | |
|---|---|
| 10 | connector with built-in ferrite core (first embodiment) |
| 12 | terminal fitting |
| 12a | first terminal fitting |
| 12b | second terminal fitting |
| 12c | third terminal fitting |
| 14 | ferrite core |
| 16 | connector housing |
| 18 | first resin portion |
| 20 | second resin portion |
| 22 | front through hole |
| 24 | rear through hole |
| 26 | one terminal portion (front terminal portion) |
| 28 | other terminal portion (rear terminal portion) |
| 30 | intermediate portion |
| 30a | first intermediate portion |
| 30b | second intermediate portion |
| 30c | third intermediate portion |
| 32 | rightward projecting portion |
| 33 | left recess |
| 34 | leftward projecting portion |
| 35 | right recess |
| 36 | narrow portion |
| 38 | arrangement region |
| 39 | internal space |
| 40 | upper part |
| 42 | lower part |
| 44 | left part |
| 46 | right part |
| 47a | upper connecting portion |
| 47b | lower connecting portion |
| 48 | upper ferrite core |
| 50 | lower ferrite core |
| 52, 52a, 52b | inner peripheral surface |
| 54, 54a, 54b | outer peripheral surface |
| 56, 56a, 56b | front end surface (one axial end surface) |
| 58, 58a, 58b | rear end surface (other axial end surface) |
| 59 | leg portion |
| 60 | bolt insertion hole |
| 62 | collar |
| 64 | primary molded product |
| 66a | upper surface (surface) |
| 66b | lower surface (surface) |
| 68 | projection |
| 70 | outer surface covering portion |
| 72 | filling portion |
| 80 | connector with built-in ferrite core (second embodiment) |
| 82 | second resin portion |
| 84 | outer surface covering portion |
| 86 | exposure hole |
| 90 | connector with built-in ferrite core (third embodiment) |
| 92 | second resin portion |
| 94 | outer surface covering portion |
| 96 | exposure hole |

1. A connector with a built-in ferrite core, comprising:
a terminal fitting;
a ferrite core arranged to surround the terminal fitting; and
a connector housing for accommodating the terminal fitting and the ferrite core,
the connector housing including a first resin portion for holding the terminal fitting in an embedded state and a second resin portion for holding the first resin portion and the ferrite core in an embedded state.

2. The connector of claim 1, wherein the second resin portion is made of a resin material higher in heat resistance than PVC.

3. The connector of claim 1, wherein:
the ferrite core is annularly arranged to surround the first resin portion, and
the second resin portion integrally includes a filling portion for filling between an inner peripheral surface of the ferrite core and a facing surface of the first resin portion and an outer surface covering portion for covering an outer peripheral surface and a pair of axial end surfaces of the ferrite core.

4. The connector of claim 3, wherein a projection projecting toward the inner peripheral surface of the ferrite core is provided on a surface of the first resin portion.

5. The connector of claim 4, wherein a plurality of the projections are distributed and arranged on the surface of the first resin portion while being spaced apart from each other in a circumferential direction.

6. The connector of claim 3, wherein the outer surface covering portion includes an exposure hole for exposing the ferrite core.
